(19) United States
(12) Patent Application Publication
(10) Pub. No.: US 2009/0201739 A1
(43) Pub. Date: Aug. 13, 2009

(54) METHOD FOR DRIVING SEMICONDUCTOR DEVICE, AND SEMICONDUCTOR DEVICE

(75) Inventor: Masayuki Terai, Tokyo (JP)

Correspondence Address: YOUNG & THOMPSON, 209 Madison Street, Suite 500, ALEXANDRIA, VA, 22314, US

(73) Assignee: NEC Corporation, Minato-=Ku Tokyo (JP)

(21) Appl. No.: 12/304,322

(22) PCT Filed: Apr. 24, 2007
(86) PCT No.: PCT/JP2007/058846

§ 371 Date: Dec. 11, 2008

(30) Foreign Application Priority Data
Jun. 12, 2006 (JP) 2006 161876

(51) Int. Cl. G11C 16/06; G11C 11/34; H01L 29/792

(52) U.S. Cl. 365/185.18; 365/184; 257/324; 257/E29.309

(57) ABSTRACT

In a case of writing to a trap type non-volatile memory cell that includes: a laminated insulating film, containing a charge accumulation layer, that is formed on a semiconductor substrate where source, drain and well regions are formed; and a first gate electrode formed on the laminated insulating film, charge injections that are carried on a single memory node multiple times under two or more different writing conditions, the writing condition is a combination of a well voltage applied to the well, a drain voltage applied to the drain and a gate voltage is applied to the first gate. Thereby, it is possible to form a trapezoid-shaped electron distribution in the charge accumulation layer, and thus prevent the charge retention characteristic from deteriorating.

### TECHNICAL FIELD

The present invention relates to a semiconductor device and a method of driving a semiconductor device, particularly to a method of driving a trap type non-volatile memory with excellent retention characteristic in terms of signal charge.

### BACKGROUND ART

In the technology concerning miniaturization of flash memory, the mainstream development up till the 0.13 μm-generation of flash memories concerns reduction in the cell area and thinning of the insulating film using a floating gate (FG) type memory. However, after the 90 nm-generation, a trap type memory, which uses a trap inside the insulating film in charge trapping, has come to attract attention, given the situation that thinning of the insulating film has become difficult in view of the problem of considering the aspect of securing the charge retention characteristic. The trap type memory shows advantages over the FG type memory in the aspect that it is successive in having a thinned tunnel oxide film and in reducing an oxide film reduced film thickness, that it has a simpler device structure as compared to the FG type, and so forth. Moreover, by using the locality of the electric charge, the FG type is capable of realizing a written state equivalent of two or more bits per cell, which is advantageous in terms of reduction in cell area per bit. Trap type memories in the related art are disclosed in Japanese Patent Laid-Open No. 2002-222678 and Japanese Patent No. 3249811, for instance.

FIG. 1 is a plane view showing a typical trap type memory in the related art. As sown in FIG. 1, the trap type memory has element separation regions 9 arranged at predetermined areas of a semiconductor substrate, whereby active regions each including source/drain regions (bit lines B1 and B2) 4 and 5 are defined. Multiple first gate electrodes (word gates WG) 1 are passed transversely across the active regions. Charge accumulation film (charge trap layer) 7 is sandwiched in between gate electrode 1 and the active region. Each gate electrode 1 includes gate sidewall 2 and sidewall 3.

FIG. 2a and FIG. 2b are sectional views of the trap type memory in the related art taken at line I-I′ and line II-II′ in FIG. 1, respectively. First gate insulating film 6, charge accumulation film 7 and second gate insulating film 8 are formed on silicon substrate 10 which includes element separation region 9. A gate electrode portion composed of first gate electrode 1 and gate sidewall 2, and sidewall 3 are formed on second gate insulating film 8. Source/drain regions (bit line B1 and bit line B2) 4 and 5 are formed on silicon substrate 10. Here, areas in charge accumulation film 7 around beneath both edge portions of gate electrode 1 are to be charge accumulation regions of node 1 and node 2

FIG. 3 is a flow chart showing an operation flow in an operation of writing to node 2 according to the related art. FIG. 4 shows voltage pulses to be applied to word gate WG, bit line B1 and bit line B2, respectively, at the time of writing.

At step 1, a positive voltage is to be applied to bit line B2 while bit line B1 is taken as a reference voltage, and an electronic current is to be discharged from bit line B1 to bit line B2 by letting the positive voltage be applied to word gate WG, whereby channel hot electrons (CHE) generated near bit line B2 will be injected into the charge accumulation film. In this way, node 2 will be brought to a written state. As shown in FIG. 4, writing is carried out by applying voltage pulses several times. In this connection, at step 2, it is to be confirmed as to whether the amount of writing has reached a predetermined amount of writing every time the voltage pulse is applied. Such method of writing and confirming in the related art is disclosed in Japanese Patent Laid-Open No. 2005-44454 and Japanese Patent Laid-Open No. 2006-12382, for instance.

FIG. 5 is a diagram illustrating a principle of detecting the amount of written charges. In detecting the amount of written charges, a positive voltage is applied to bit line B1 and an electronic current is discharged from bit line B2 to bit line B1 by sweeping word gate WG to the positive voltage. At this time, the threshold voltage of word gate WG voltage for letting the amount of electronic current reach a certain predetermined value will change depending on the amount of written charges in node 2. This happens because the work function in the vicinity of node 2 will change in a positive direction due to electron accumulation, which makes it difficult for an inversion layer to be formed. The amount of accumulated charges can be grasped by monitoring such changes in the threshold voltage. In this respect, by repeating the charge injection until the threshold voltage reaches a predetermined value, as indicated in FIG. 3, it will be possible to render the amount of written charges a predetermined amount. The method of detecting the amount of written charges in the related art is also disclosed in Japanese Patent Laid-Open No. 1995-153924, for example.

As miniaturization of word gate WG progresses for the purpose of improving on-current characteristics, it has become necessary to make an impurity concentration profile in the boundary between diffusion layers 4 and 5 and substrate 10 a precipitous form, in order to prevent a punch-through current from flowing in between bit lines B1 and B2. However, if the impurity concentration profile is rendered a precipitous form, electric field will be concentrated in the vicinity of a PN junction in between the substrate and the diffusion layers, whereby an accumulated electron distribution profile as a result of the CHE injection will exhibit a precipitous form. As shown in FIG. 6, in the case when the accumulated electron distribution profile exhibits a precipitous form, the signal intensity will change over time in a high-temperature retention test due to the accumulated charges diffusing in such a way as to relax the self-electric field in the high-temperature retention test, leading to a problem of data getting easily lost.

Japanese Patent Laid-Open No. 2006-12382 discloses a technique in which injection of CHE or SSI (source side injection) is to be carried out while lowering a memory gate voltage, after which additional injection of CHE is to be carried out while applying high voltage to the memory gate voltage, so as to be able to carry out the electron injection into the charge accumulation layer in a wide range. In this method, however, a position of electron injection will shift in a direction toward the source/drain diffusion layer, by which the latter writing will be greatly influenced by the charges accumulated in the preceding writing, leading to a problem of the charge injection speed in the latter charge injection decreasing to a considerable extent and a problem of the writing speed slowing down. This leads to a further problem in which a high gate voltage of 11 V, for instance, will be required. Moreover, since it is difficult in principle to monitor the amount of charges at a position closer to the side of the source/drain diffusion layer than the preceding charge injection position, it is impossible to reduce variation in the accumulated charge distribution per chip.

### DISCLOSURE OF THE INVENTION

It is therefore an object of the present invention to provide a method of driving a semiconductor device which enables stable data retention without using a high gate voltage.

In accordance with the method of driving a semiconductor device according to the present invention, the semiconductor device including a trap type non-volatile memory cell which includes a laminated insulating film, containing a charge accumulation layer, being formed on a semiconductor substrate where source, drain and well regions are formed, and a first gate electrode formed on the laminated insulating film, comprise: conducting charge injections on a single memory node multiple times under two or more different writing conditions, the writing condition being a combination of a well voltage that is applied to the well, a drain voltage that is applied to the drain and a gate voltage that is applied to the first gate.

The trap type non-volatile memory cell may be a kind that further includes a second gate electrode formed on the semiconductor substrate through a gate insulating film that is adjacent to the first gate electrode through an insulating film or that is sandwiched in between a pair of the first gate electrodes through insulating films.

In accordance with the method of driving a semiconductor device according to the present invention, a drain voltage applied in a latter charge injection is higher than a drain voltage applied in a former preceding charge injection, or a well voltage applied in a latter charge injection is higher than a well voltage applied in a former preceding charge injection with respect to the polarity in which a depletion layer around source/drain expands. The drain voltage applied in the latter charge injection may be higher than the drain voltage applied in the former preceding charge injection by 1 V or more, or a voltage difference between the well voltage applied in the latter charge injection and the well voltage applied in the former preceding charge injection may be 1 V or greater.

By using the charge injection method according to the present invention, it is possible to form an electron distribution of a trapezoid shape like the one shown in FIG. 8 in the charge accumulation layer, and thus prevent the charge retention characteristics from deteriorating.

Moreover, the method of driving a semiconductor device according to the present invention includes an operation of determining for each charge injection as to whether a predetermined amount of charges with respect to each writing condition has been written, by using a threshold detection condition corresponding to each writing condition.

The method of driving a semiconductor device may further comprise: injecting charges under a first writing condition, then detecting the amount of written charges written by the charge injection under the first writing condition using a channel current in a direction opposite to that at the time of the charge injection, and alternately repeating the charge injection under the first writing condition and the detection of the amount of written charges until the amount of written charges reaches a first predetermined write amount; and injecting charges under a second writing condition where a drain voltage is rendered higher than the drain voltage in which of the first writing condition or where a well voltage is changed in a direction in which a depletion layer around the source/drain expands, the charge injection being carried out in a direction that is the same as that in the case of the charge injection under the first writing condition, then detecting the amount of written charges written in the charge injection under the second writing condition using a channel current in a direction that is the same as the direction at the time of the charge injection, and alternately repeating the charge injection under the second writing condition and detecting the amount of written charges until the amount of written charges reaches a second predetermined write amount.

Alternatively, the method of driving a semiconductor device may further comprise: injecting charges under a first writing condition, then detecting the amount of written charges written by the charge injection under the first writing condition using a channel current in a direction that is the same as that at the time of the charge injection, and alternately repeating the charge writing under the first writing condition and detecting of the amount of written charges until the amount of written charges reaches a first predetermined write amount; and injecting charges under a second writing condition where a drain voltage is rendered higher than the drain voltage of the first writing condition or where a well voltage is changed in a direction in which a depletion layer around the source/drain expands, the charge injection being carried out in a direction that is the same as the direction in the case of the charge injection under the first writing condition, then detecting the amount of written charges written by the charge injection under the second writing condition using a channel current in a direction that is the same as the drain at the time of the charge injection while a pinch-off point is being shifted closer toward the source than in a written charge detection condition with respect to the charge injection under the first writing condition, and alternately repeating the charge injection under the second writing condition and detecting of the amount of written charges until the amount of written charges reaches a second predetermined write amount.

By using such method of detecting the amount of written charges, it is possible to accurately monitor the amount of written charges under each writing voltage condition, whereby, variability in electrical characteristics among elements can be resolved and the shape of the accumulated charge distribution can be made uniform.

According to the present invention, in a case of writing to one memory cell of the trap type non-volatile memory cell, the trap type non-volatile memory cell includes; the laminated insulating film, containing the charge accumulation layer, being formed on the semiconductor substrate where the source, drain and well regions are formed; and the first gate electrode being formed on the laminated insulating film, the charge writings to be conducted multiple times under two or more different writing conditions, the writing condition being a combination of a well voltage that is applied to the well, a drain voltage that is applied to the drain and a gate voltage that is applied to the first gate. Thereby, it is possible to render the shape of the accumulated charge distribution a trapezoid shape, and thus improve the charge retention characteristics to a considerable extent. Furthermore, it is possible to reduce the unevenness in the amount of written charges and in the distribution shape for each memory node. What is more, by arranging such that the drain voltage or the well voltage will be changed, it is no longer necessary to use a high gate voltage.

### BRIEF DESCRIPTION OF THE DRAWINGS

FIG. 1 is plane view showing a non-volatile memory element of a simple transistor type memory that is a typical trap type memory in the related art;

FIG. 2a is a sectional view taken at line I-I′ in FIG. 1;

FIG. 2b is a sectional view taken at line II-II′ in FIG. 1;

FIG. 3 is a flow chart showing an operation of writing to the non-volatile memory in the related art;

FIG. 4 is a diagram showing voltage pulses to be applied to respective portions of the non-volatile memory at the time of writing, according to a method in the related art;

FIG. 5 is a diagram for explaining a method of detecting the amount of charges written to the non-volatile memory according to a method in the related art;

FIG. 6 is a graphic representation showing an accumulated charge density distribution with respect to charges written to the non-volatile memory, according to a method in the related art;

FIG. 7 is a diagram showing voltage pulses to be applied to respective portions of a non-volatile memory in a method of driving a semiconductor device, according to a first exemplary embodiment;

FIG. 8 is a graphic representation showing an accumulated charge (electron) density distribution with respect to charges (electrons) accumulated into a node of the non-volatile memory using the voltage pulses shown in FIG. 7;

FIG. 9 is a diagram showing voltage pulses to be applied to respective portions of a non-volatile memory in a method of driving a semiconductor device, according to another exemplary embodiment;

FIG. 10 is a flow chart showing an operation of writing charges to a node under some writing conditions in a method of driving a semiconductor device, according to a second exemplary embodiment;

FIG. 11 is a diagram showing voltage pulses to be applied to respective portions of a non-volatile memory in a case of writing to the node according the flow chart of FIG. 10;

FIG. 12a is a diagram for explaining write amount detection condition A corresponding to a first writing condition, for explaining the write amount detection operation of FIG. 10 and FIG. 11;

FIG. 12b is a diagram for explaining write amount detection condition B corresponding to a second writing condition, for explaining the write amount detection operation of FIG. 10 and FIG. 11;

FIG. 13a is a diagram for explaining write amount detection condition A′ corresponding to a first writing condition, for explaining another example of the write amount detection operation of FIG. 10 and FIG. 11;

FIG. 13b is a diagram for explaining write amount detection condition B′ corresponding to a second writing condition, for explaining another example of the write amount detection operation of FIG. 10 and FIG. 11;

FIG. 14 is a graphic representation of a writing characteristic indicating writing period (Prog. Time) dependency of threshold voltage VT in a case when writing is carried out according to a writing method in the related art;

FIG. 15 is a graphic representation of a writing characteristic indicating writing period (Prog. Time) dependency of threshold voltage VT in a case when writing is carried out in accordance with a method of driving a semiconductor device, according to a first example;

FIG. 16a is a diagram showing several kinds of writing conditions;

FIG. 16b is a graphic representation showing changes in threshold voltage in a case when a baking process at a temperature of 150° C. is carried out after writing is carried out using each of the conditions shown in FIG. 16a;

FIG. 17 is a plane view showing a TWINMONOS type non-volatile memory element to which the present invention is applicable;

FIG. 18a is a sectional view taken at line I-I′ in FIG. 17;

FIG. 18b is a sectional view taken at line II-II′ in FIG. 17;

FIG. 19 is a diagram showing one example of voltage pulses to be applied to respective portions of the TWINMONOS type memory in the method of driving a semiconductor device, according to the present invention;

FIG. 20 is a diagram showing another example of voltage pulses to be applied to respective portions of the TWINMONOS type memory in the method of driving a semiconductor device, according to the present invention; and

FIG. 21 is a diagram showing still another example of voltage pulses to be applied to respective portions of the TWINMONOS type memory in the method of driving a semiconductor device, according to the present invention.

### BEST MODE FOR CARRYING OUT THE INVENTION

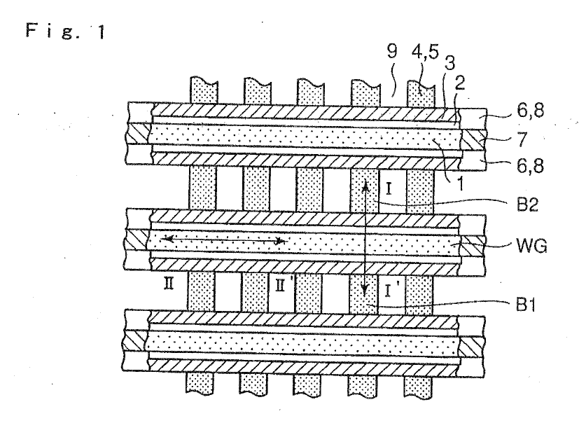

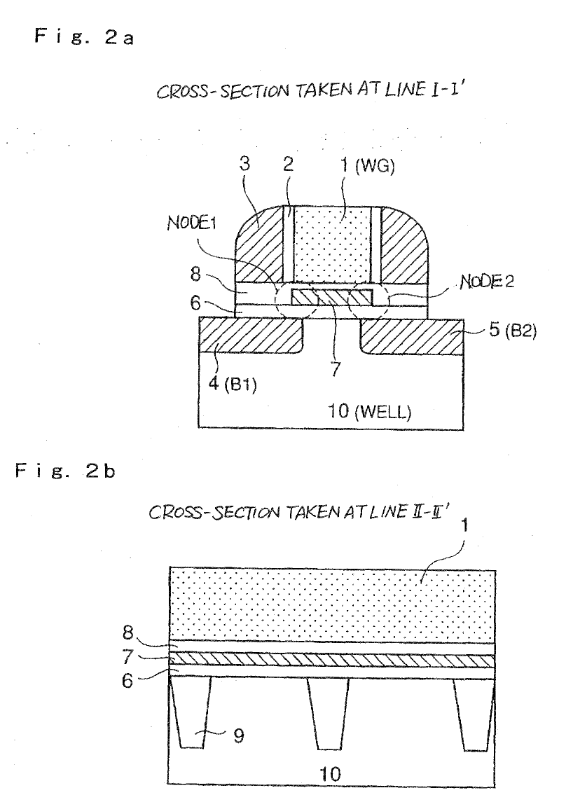

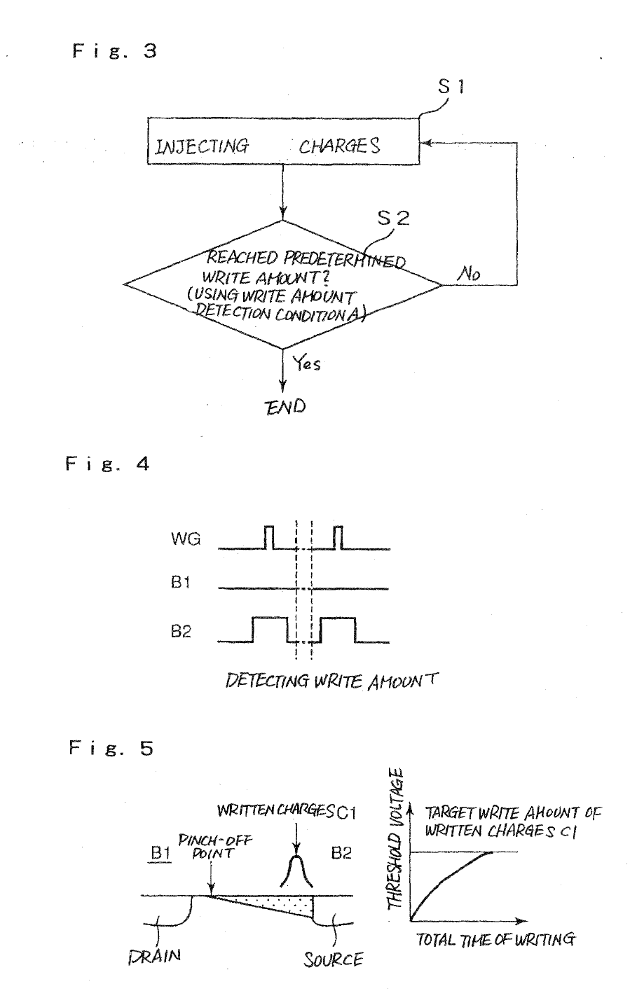

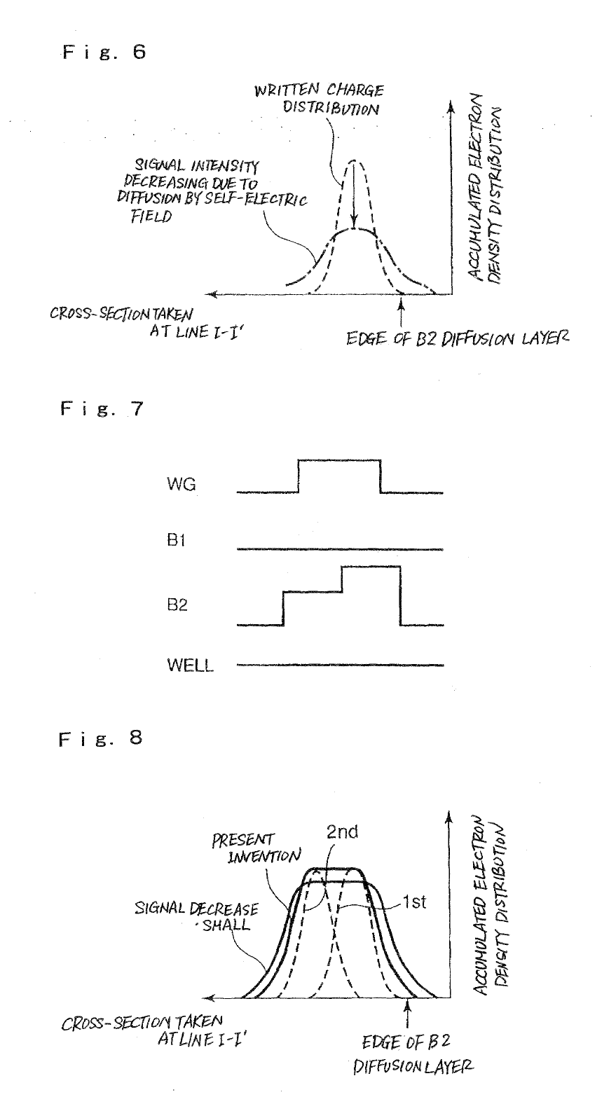

In the following, exemplary embodiments will be described in detail with reference to the drawings. It will be assumed that charges are to be written to memory node 2 of a common trap type non-volatile memory in the same way as the one shown in FIG. 1 and FIG. 2.

FIG. 7 is a diagram showing voltage pulses to be applied to word gate WG, bit line B1, bit line B2 and a WELL, respectively, in a case of writing charges to memory node 2 using a method of driving a semiconductor device, according to a first exemplary embodiment.

As shown in FIG. 7, by applying a positive voltage to bit line B2, which will become a drain, and to a first gate electrode (WG), while bit line B1, which will become a source, and the WELL are taken as a reference voltage, an electronic current will flow in an inversion layer underneath the gate electrode from the source toward the drain. At this time, since the area around the drain region is inversely-biased with respect to the WELL, a depletion layer will be formed around the drain region, and thus a high electric field region will be formed. Then channel hot electrons generated due to the high electric field effect around the drain region will be injected into charge accumulation layer 7 while part of the injected channel hot electrons will be accumulated in charge accumulation layer 7. Thus, memory node 2 can be changed from an erased state to a written state.

A written state, by definition, is a state in which a channel current becomes a certain prescribed current value or below a certain proscribed current value due to the effect in which the electrons accumulated in charge accumulation layer 7 in the vicinity of bit line B2 let the work function in that area shift in a positive direction, in a case when an electronic current is discharged from bit line B2 to bit line B1, bit line B2 being a source, as opposed to the case of writing, by applying a positive voltage to bit line B1 and word gate WG while bit line B2 and the WELL are taken as a reference voltage.

With respect to the driving method according to the present exemplary embodiment, the voltage of bit line B2 at the time of writing will be in two levels, while writing will be first carried out with a lower bit line B2 voltage after which writing will be carried out with a higher bit line B2 voltage. As mentioned earlier, the channel hot electrons are generated due to the high electric field effect in the vicinity of the drain, and therefore, when the voltage of bit line B2 is raised, the depletion layer around the drain (bit line B2) region will further expand in a direction toward the source (bit line B1), while the position where the channel hot electros are to be generated will also shift in the direction toward the source. Accordingly, in the case of using the driving method according to the present exemplary embodiment as shown in FIG. 7, it is possible to obtain a distribution density of electrons accumulated in charge accumulation layer 7 (i.e. accumulated electron density distribution) in a trapezoid shape as shown in FIG. 8. In the trapezoid-shaped accumulated electron density distribution, deterioration in signal intensity can be kept small in the high-temperature retention test.

It is preferable that the bit line B2 voltage in the latter writing be set as higher than the bit line B2 voltage in the former writing by 1 V or more. By arranging the bit line B2 voltage as having a voltage difference of 1 V or more with respect to the bit line B2 voltage in the former writing, it is possible to sufficiently separate the peak of charge distribution in the former writing from the peak of a charge distribution in the latter writing, which allows an ideal trapezoid-shaped accumulated charge distribution to be formed.

Although the bit line B2 voltage is changed to a higher voltage in FIG. 7, it is also possible to change the bit line B2 voltage to a lower voltage in the second writing and after that, which also allows a similar accumulated charge density distribution to be formed. In the case of lowering the bit line B2 voltage in the second writing and after that, however, the amount of electronic current flowing in the inversion layer will decrease considerably due to the influence of the electrons accumulated in the first writing, whereby it becomes necessary to raise the word gate WG voltage at the time of writing by a considerable amount. Therefore, in the present exemplary embodiment, the bit line B2 voltage is to be changed to higher voltage. In the case of raising the bit line B2 voltage in the latter electron injection, the electron accumulated region generated by the former electron injection will enter an area closer toward the depletion layer than the pinch-off point, whereby reduction in the amount of electronic current flowing in the inversion layer can be prevented.

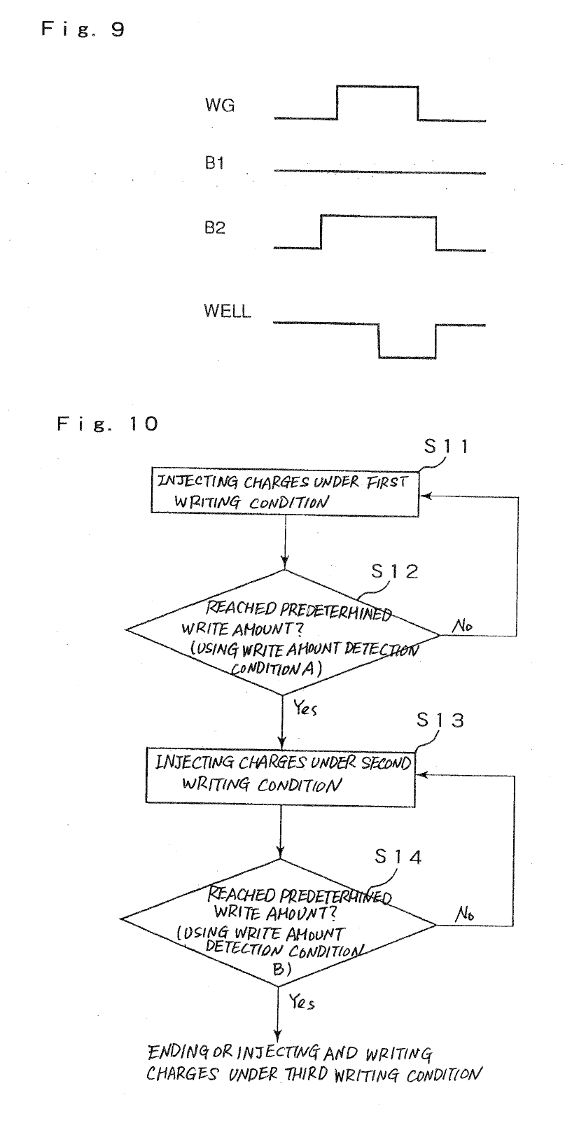

Moreover, as shown in FIG. 9, it is also possible to change the depletion layer around the drain (B2) region by changing the WELL voltage in a negative direction without changing the bit line B2 voltage at the time of electron injection, which also allows the same kind of effect as in the case of changing the bit line B2 voltage to be obtained.

Normally, it is difficult to change the electric potential of the WELL region having a large capacity by applying a short-term pulse. Therefore, first, a certain voltage is to be applied to the WELL, and then after a lapse of a certain period of time sufficient for the WELL voltage to stabilize, certain voltage pulses are applied to bit line B2 and word gate WG in order to accurately control the charge injection period under a first writing condition. Then, after one or more writing operations with the first WELL voltage, a second voltage is applied to the WELL, and then after a lapse of a certain period of time sufficient for the WELL voltage to stabilize, certain voltage pulses are applied to bit line B2 and word gate WG in order to accurately control the charge injection under a second writing condition.

In the case of carrying out writing by changing the WELL voltage, it is also preferable that the WELL voltage in the latter writing is set as higher than the WELL voltage in the former writing by 1 V or more. By arranging the WELL voltage to have a voltage difference of 1 V or more with respect to the WELL voltage in the former writing, it is possible to sufficiently separate the peak of charge distribution in the former writing from the peak of a charge distribution in the latter writing, which allows an ideal trapezoid-shaped accumulated charge distribution to be formed.

Next, a method of driving a semiconductor device according to a second exemplary embodiment will be described. In the present exemplary embodiment also, it will be assumed that charges will be written to memory node 2 of a common trap type non-volatile memory in the same way as the one shown in FIG. 1 and FIG. 2.

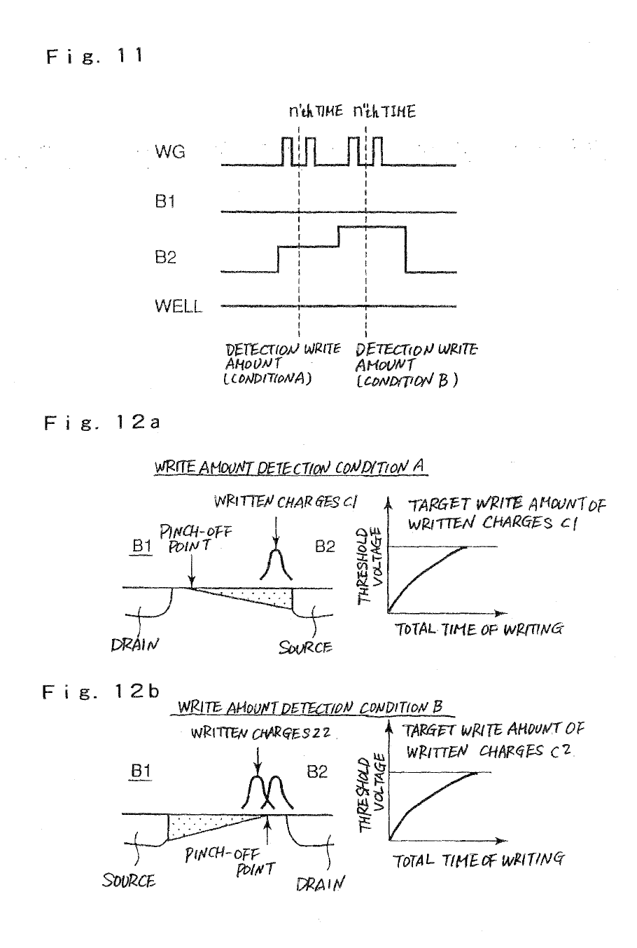

FIG. 10 is a flow chart showing a flow of operation in writing charges to node 2 under some writing conditions. FIG. 11 is a diagram showing voltage variations to be applied to word gate WG, bit line B1, bit line B2 and the WELL, respectively, in a case of carrying out the writing according to the operation flow shown in FIG. 10.

In the present exemplary embodiment, as shown in FIG. 10 and FIG. 11, an electron injection is to be carried out one or more times under a first writing condition at step 11, and after each electron injection, it will be checked to determine whether the amount of injected electrons has reached a predetermined value at step 12. If the checked result indicates that the amount of injected electrons has reached a first predetermined value, then at step 13, an electron injection will be carried out under a second writing condition where the bit line B2 voltage is changed to a voltage higher than that in the first writing condition. The electron injection under the second writing condition will also be carried out one or more times, and after each electron injection, it will be checked to determine whether the amount of injected electrons has reached a second predetermined value at step 14.

By using different write amount detection conditions between the case of injecting electrons under the first writing condition and the case of injecting electrons under the second writing condition, it is possible to adjust the amount of injected electrons under each of the first and the second writing conditions to a desired amount. As a result, unevenness in the accumulated electron distribution density and in the distribution form among elements can be reduced, whereby variability in electrical characteristics at the time of writing can be resolved.

In FIG. 11, a writing period is controlled by a period of applying a voltage pulse to word gate WG, word gate WG having the voltage pulse applied to while a certain voltage is being applied to bit line B2. However, it is also possible to control the writing period by a period of applying a voltage pulse to bit line B2, bit line B2 having the voltage pulse applied to while a certain voltage is being applied to word gate WG.

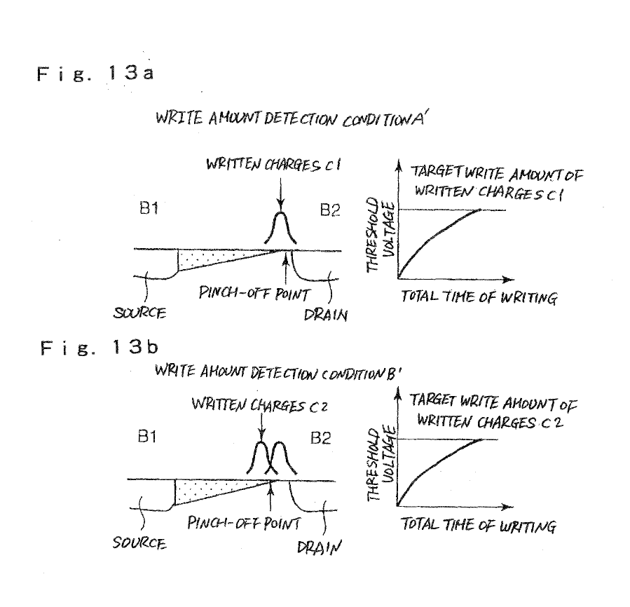

Next, a method of checking (detecting) the amount of written charges will be described in detail with reference to FIG. 12a and FIG. 12b.

With respect to the charge injection under the first writing condition, the amount of written charges will be detected using a channel current in a direction opposite to that at the time of writing, as shown in FIG. 12a. In this case, written charges C1 will greatly influence the channel current, whereby a threshold voltage of word gate WG necessary for the channel current to reach a certain current value will rise depending on the value of written charges C1. Therefore, it is possible to monitor the amount of written charges C1 using the threshold voltage of word gate WG.

On the other hand, with respect to the charge writing under the second writing condition using a drain voltage higher than that of the first writing condition, the amount of written charges will be detected using a channel current in a direction the same as that at the time of charge writing, as shown in FIG. 12b. In this case, since written charges C1 will enter an area closer toward the drain than a pinch-off point, it will have little influence on the channel current, whereas written charges C2 written under the second charge writing condition will have greater influence over the channel current. Accordingly, it is possible to monitor the amount of written charges C2 using the threshold voltage of word gate WG which is necessary for letting the channel current flow in the same direction as in the case of writing.

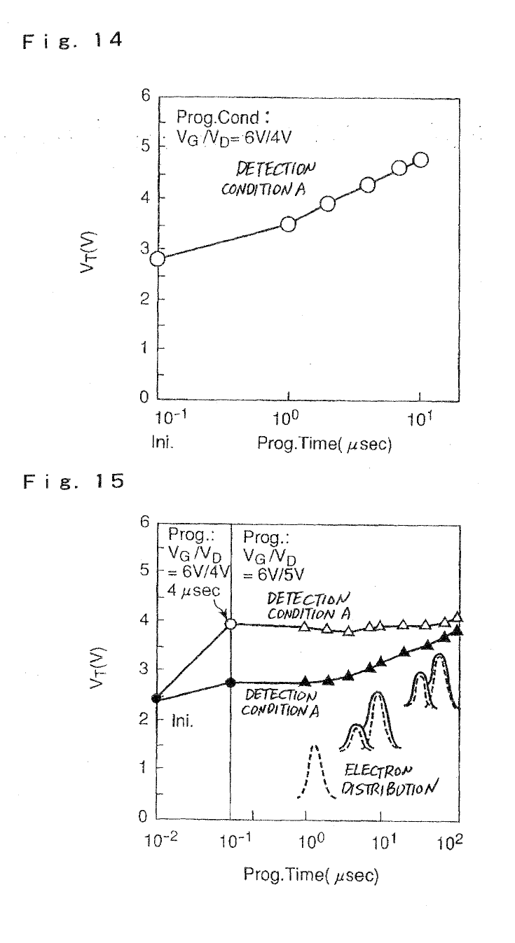

Next, another method of detecting the amount of written charges will be described with reference to FIG. 13a and FIG. 13b.

With respect to charge injection under the first writing condition, the amount of written charges will be detected using a channel current in the same direction as in the case of writing, as shown in FIG. 13a. That is, while the word gate WG voltage is taken as a threshold voltage for letting the channel current reach a certain current value, it is to be determined whether the amount of written charges has reached the first predetermined amount by determining whether the threshold voltage of word gate WG has reached a certain predetermined value. At this time, the drain voltage will be lowered sufficiently such that a pinch-off point will be positioned closer toward the drain than the center of distribution of written charges C1.

On the other hand, with respect to the charge writing under the second writing condition where a drain voltage is rendered higher than the drain voltage that of the first writing condition or where the WELL voltage is changed in a direction in which the depletion layer around the source/drain expands, the amount of written charges will be detected in the following manner. In this case also, the amount of written charges will be detected using a channel current in a direction that is the same as the direction that at the time of writing, as shown in FIG. 13b. More specifically, while word gate WG is being taken as a threshold voltage for letting the channel current reach a certain current value, the channel current flows in a direction the same as in the cases of the first and the second charge writings while a pinch-off point is being shifted toward the source, it is to be determined whether the amount of written charges has reached the second predetermined amount by determining as to whether the threshold voltage of word gate WG has reached a certain predetermined value. The pinch-off point can be shifted toward the source by changing the drain voltage or the WELL voltage in the direction in which the depletion layer around the source/drain expands. In the case when the pinch-off point is closer toward the source than a center of the charge distribution under the first writing condition, while it is closer toward the drain than the center of the charge distribution under the second writing condition, the channel current will be greatly influenced by the charges written under the second writing condition, and therefore, it is possible to monitor the amount of written charges C2 using the threshold voltage of word gate WG.

Using such flow of writing operation as described above, it is possible to reduce unevenness in the amount of written charges and in distribution shape with respect to each memory node. Furthermore, by rendering the shape of the accumulated charge distribution a trapezoid shape, it is possible to improve the charge retention characteristics to a considerable extent with little variability.

### First Example

Next, a specific example of a case in which the method of driving a semiconductor device, according to the present invention, is applied to a SONOS type non-volatile memory, will be described in detail. A device structure used for the evaluation is the same as the one shown in FIG. 1 and FIG. 2. In this case, an oxide film formed by ISSG (in situ steam generation) is used as first gate insulating film 6, a CVD-Si3N4 film is used as charge accumulation film 7, and an oxide film formed by oxidizing an upper part of the CVD nitride film is used as second gate oxide film 8. Film thicknesses of the upper oxide film, the nitride film and the lower oxide film directly underneath gate electrode 1 are 4 nm, 4 nm and 5 nm, respectively.

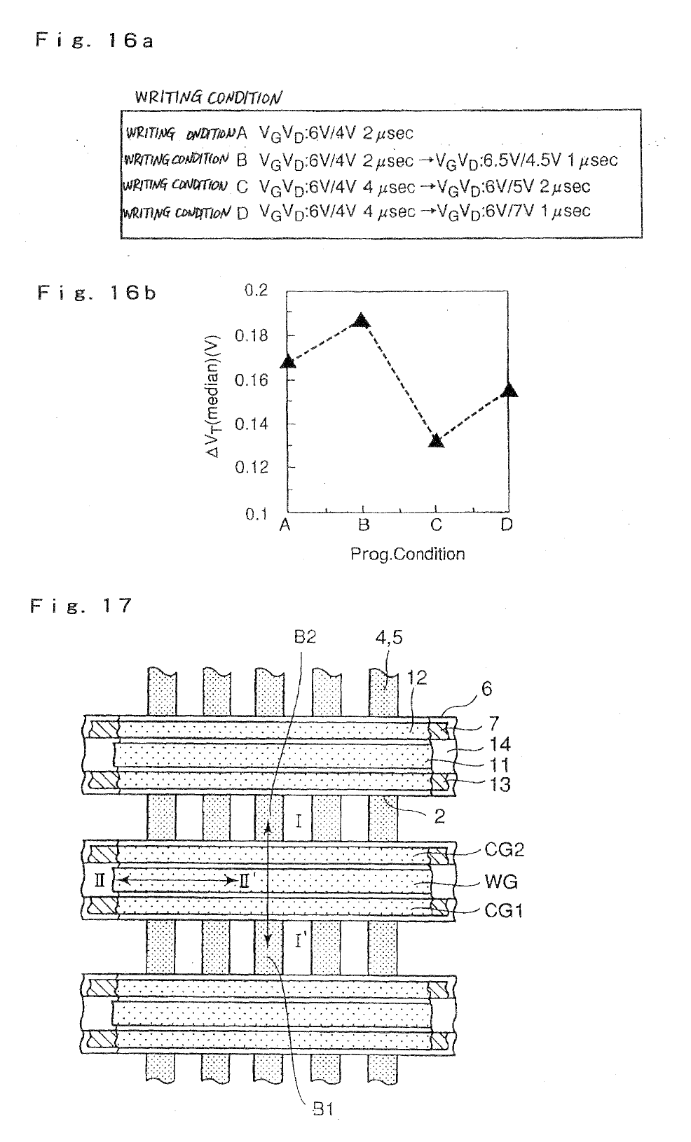

FIG. 14 shows a writing characteristic when writing (charge injection) to node 2 is carried out, while bit line B1 is taken as a source and bit line B2 is taken as a drain, and under a writing condition (writing condition in the related art) where; a drain voltage (VD) is 4 V, a word gate WG voltage (VG) is 6 V, a source voltage (VS) is 0 V, and a WELL voltage (VWELL) is 0 V. Detection of a threshold voltage (VT) is carried out with a detecting method (detection condition A) in which bit line B1 is taken as a drain (VD=1.2 V) and bit line B2 is taken as a source (VS=0 V), which is opposite to the case of writing, and in which a word gate WG voltage that renders the channel current 5E-6 A is detected as the threshold voltage (VT). It can be seen from FIG. 14 that the amount of accumulated charges in the vicinity of node 2, which is an edge portion of the source, at the time of threshold voltage detection increase as the writing period increase, and that threshold voltage VT is becoming higher.

Next, FIG. 15 shows a writing characteristic when charge writing is first carried out under the first writing condition, for 4 μsec after which additional charges are injected to node 2 under the second writing condition.

In the first writing condition applied for this case, the drain voltage (VD) is 4 V, the word gate WG voltage (VG) is 6 V, the source voltage (VS) is 0 V, and the WELL voltage (VWELL) is 0 V. In the second writing condition applied for this case, the drain voltage (VD) is 5 V, the word gate WG voltage (VG) is 6 V, the source voltage (VS) is 0 V, and the WELL voltage (VWELL) is 0 V. In this case, threshold voltage detection is to be carried out using: detection condition A where bit line B1 is taken as a drain (VD=1.2 V) and bit line B2 is taken as a source (VS=0 V) while the threshold voltage of word gate WG is to be detected from a channel current flowing from bit line B2 to bit line B1, and detection condition B where bit line B2 is taken as a drain (VD=1.2 V) and bit line B1 is taken as a source (VS=0 V) while a threshold voltage of word gate WG is detected from a channel current flowing from bit line B1 to bit line B2.

As shown in FIG. 15, with detection condition A, threshold voltage VT as detected, shows almost no change by the additional writing, whereas with detection condition B, threshold voltage VT, as detected, is increased by the additional writing. The reason that threshold voltage VT shows hardly any change under detection condition A is because the accumulated charges under the first writing condition have greatly influenced threshold voltage VT since the accumulated charge region of node 2 is closer toward the source than the pinch-off point, whereby the accumulated charges under the second writing condition are rendered hardly detectable. On the other hand, under detection condition B, since the pinch-off point is positioned in between the center of accumulated charge distribution under the first writing condition and the center of accumulated charge distribution under the second writing condition, it is possible to accurately detect the amount of accumulated charges written under the second writing condition. Therefore, it is possible to control the amount of accumulated charges written under the second writing condition to a desired amount.

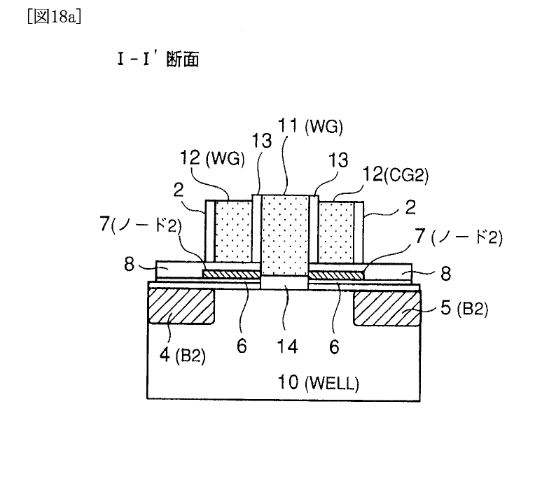

FIG. 16a shows: writing condition A (writing method in the related art) where VG/VD=6 V/4 V and the writing period is 2 μsec; writing condition B where VG/VD=6 V/4 V and the writing period is 2 μsec for the initial writing, and where VG/VD=6.5 V/4.5 V and the writing period is 1 μsec for the subsequent writing; writing condition C where VG/VD=6 V/4 V and the writing period is 4 μsec for the initial writing, and where VG/VD=6 V/5 V and the writing period is 2 μsec for the subsequent writing; and writing condition D where VG/VD=6 V/4 V and the writing period is 4 μsec for the initial writing, and where VG/VD=6 V/7 V and the writing period is 1 μsec for the subsequent writing. FIG. 16b shows changes in threshold voltage VT under a baking process at a temperature of 150° C. in the cases of carrying out writings under writing conditions A to D.

As shown in FIG. 16b, underwriting condition B, no reduction effect in the variation of threshold voltage VT as compared to the writing method in the related art (writing condition A) is exhibited. On the other hand, under writing conditions C and D, where the drain voltage is increased by 1 V or more as compared to the writing condition for the first writing, a reduction effect in the variation of threshold voltage VT is noted, which indicates that the charge retention characteristics have been improved.

It can be considered that the reason why no effect has been exhibited under writing condition B is because the center of written charge distribution did not shift so much due to the amount of drain voltage increased being small at 0.5 V under the second writing condition, whereby the accumulated electron distribution did not assume an ideal trapezoid shape. However, by letting an impurity concentration profile of the source/drain become more gentle, the pinch-off point will be able to move more easily, which enables the charge retention characteristics to improve, even with variation of applied voltage is less than 1 V.

As described above, it has been proven that by using the method of driving a semiconductor device, according to the present invention, it is possible to make, with good controllability, the shape of the accumulated charge distribution into a trapezoid shape, and thus improve the charge retention characteristics.

### Second Example

Now, a case in which the method of driving a semiconductor device, according to the present invention, is applied to a TWINMONOS type trap memory will be described in detail.

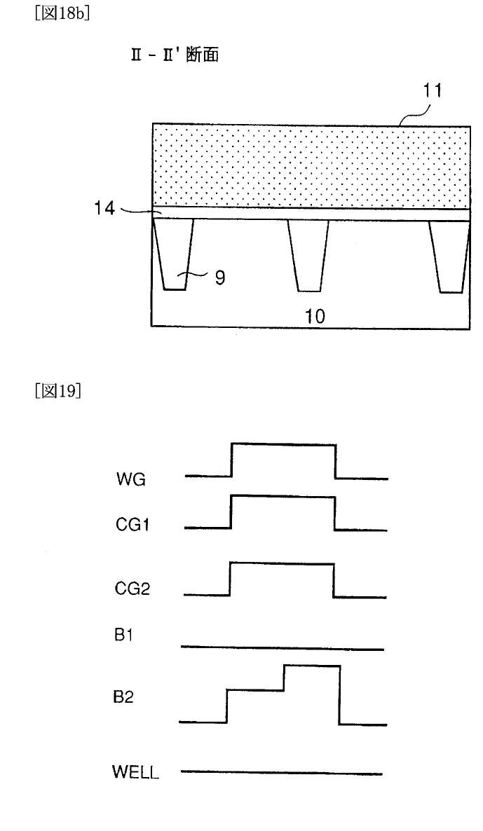

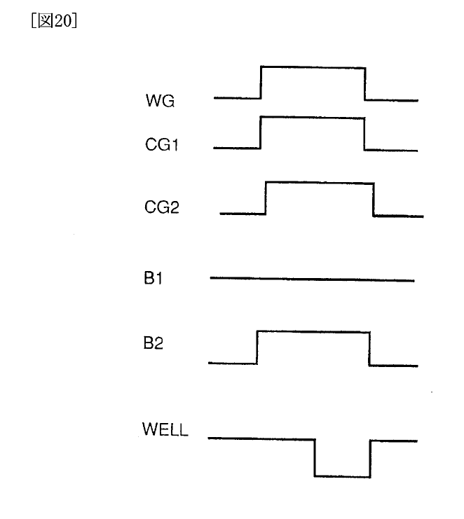

FIG. 17 is a plane view showing the TWINMONOS type trap memory. FIG. 18a is a sectional view taken at line I-I′ in FIG. 17 and FIG. 18b is a sectional view taken at line II-II′ in FIG. 17.

In the case of the TWINMONOS type trap memory, control gates 12 (CG1 and CG2) are arranged on both sides of word gate (WG) through inter-gate insulating films 13, respectively. Control gates 12 configure a pair of first gate electrodes while word gate 11 sandwiched in between control gates 12 is configures a second electrode.

Underneath each control gate 12, first gate insulating film 6, charge accumulation film 7 and second gate insulating film 8 are being formed. A charge accumulation region positioned underneath control gate CG1 will be node 1, and a charge accumulation region positioned underneath control gate CG2 will be node 2.

Moreover, gate insulating film 14 for word gate is being formed underneath word gate 11.

FIG. 19 is a diagram showing voltage pulses that are applied to word gate WG, control gates CG1 and CG2, bit lines B1 and B2, and a WELL, respectively, in a case when charges are written to memory node 2 while the method of driving a semiconductor device, according to the present invention, is applied to the trap memory of FIG. 18.

As shown in FIG. 19, by applying a positive voltage to bit line B2, which will become a drain, first gate electrodes CG1 and CG2, and word gate WG, while bit line B1, which will become a source, and the WELL are taken as a reference voltage, an electronic current will flow in an inversion layer underneath the gate electrode from the source toward the drain. Since the area around the drain region is inversely-biased with respect to the WELL, a depletion layer will be formed around the drain, and thus a high electric field region will be formed. At this time, channel hot electrons generated due to the high electric field effect in the vicinity of the drain region will be injected into charge accumulation layer 7 while part of the injected channel hot electrons will be accumulated in charge accumulation layer 7. Thus, node 2 can be changed from an erased state to a written state.

In the present exemplary embodiment, the voltage of bit line B2 will be in two levels at the time of writing, while writing will first carried out with a lower bit line B2 voltage after which writing will be carried out with a higher bit line B2 voltage. As mentioned earlier, the channel hot electrons are generated due to the high electric field effect in the vicinity of the drain. Therefore, when the voltage of bit line B2 is raised, the depletion layer in the vicinity of the drain (bit line B2) region will further expand in a direction toward the source (bit line B1), while the position where the channel hot electros will be generated will shift also in the direction toward the source. Accordingly, by using the voltage pulses shown in FIG. 19 for writing, it is possible to form an accumulated electron density distribution having a trapezoid shape as shown in FIG. 8.

Although the bit line B2 voltage is changed to a higher voltage in FIG. 19, it is also possible to change the bit line B2 voltage to a lower voltage in the second writing and after that, which also allows a similar accumulated charge density distribution to be formed. In the case of lowering the bit line B2 voltage in the second writing and after that, however, the amount of electronic current flowing in the inversion layer will decrease considerably due to the influence of the electrons accumulated in the first writing, whereby it becomes necessary to raise word gate voltage VG at the time of writing by a considerable amount. Therefore, as explained with respect to the case of the first exemplary embodiment, in the present exemplary embodiment also, the bit line B2 voltage will be changed to higher voltage. In the case of raising the bit line B2 voltage in the latter electron injection, the electron accumulated region generated by the former electron injection will enter an area closer toward the depletion layer than the pinch-off point, whereby a reduction in the amount of electronic current flowing in the inversion layer can be prevented.

Moreover, as shown in FIG. 20, it is also possible to change the depletion layer in the vicinity of the drain (bit line B2) region by changing the WELL voltage in a negative direction without changing the bit line B2 voltage at the time of electron injection, which also allows the same kind of effect as in the case of changing the bit line B2 voltage to be obtained.

Normally, it is difficult to change the electric potential of the WELL region that has a large capacity by applying a short-term pulse. Therefore, first, a certain voltage will be applied to the WELL, and then after the WELL voltage is stabilized, certain voltage pulses will be applied to bit line B2 and control gate CG2 in order to accurately control the charge injection period under a first writing condition. Then, after one or more writing operations under the first WELL voltage, a second voltage will be applied to the WELL, and then after a lapse of a certain period of time sufficient for the WELL voltage to stabilize, certain voltage pulses will be applied to bit line B2 and control gate CG2 in order to accurately control the charge injection period under a second writing condition.

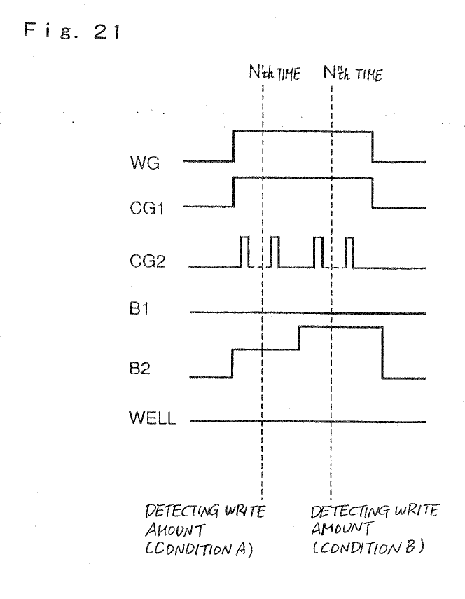

Writing to node 2 can be carried out according to the same operation flow as shown in FIG. 10. In this case, as shown in FIG. 21, an electron injection will be carried out one or more times under a first writing condition, and after each electron injection, whether the amount of injected electrons has reached a first predetermined value will be determined. Then after the amount of injected electrons has reached the first predetermined value, an electron injection will be carried out under a second writing condition where the bit line B2 voltage is higher than that in the first writing condition. The electron injection under the second writing condition will also be carried out one or more times, and after each electron injection, whether the amount of injected electrons has reached a second predetermined value will be checked. At this time, by using different write amount detection conditions after injecting electrons under the first writing condition and after injecting electrons under the second writing condition, respectively, it is possible to adjust the amount of injected electrons under each of the first and the second writing conditions to a desired amount. In other words, unevenness in the accumulated electron distribution density and in the distribution form among elements can be reduced, whereby variability in electrical characteristics at the time of writing can be resolved.

In FIG. 21, a writing period is controlled by a period of applying a voltage pulse to control gate CG2, control gate CG2 having the voltage pulse applied to after a certain voltage is being applied to bit line B2, word gate WG and control gate CG1. However, it is also possible to control the writing period by a period of applying a voltage pulse to control gate CG1, control gate CG1 having the voltage pulse applied to after a certain voltage is being applied to bit line B2, word gate WG and control gate CG2. Or else, it is also possible to control the writing period by a period of applying a voltage pulse to word gate WG, word gate WG having the voltage pulse applied to after a certain voltage is being applied to bit line B2, and control gates CG1 and CG2. In addition, it is also possible to control the writing period by a period of applying a voltage pulse to bit line B2, bit line B2 having the voltage pulse applied to after a certain voltage is being applied to word gate WG, and control gates CG1 and CG2.

In respect of detecting the amount of written charges, with respect to the charge injection under the first writing condition, the amount of written charges will be detected using a channel current in a direction opposite to that at the time of writing. Then, with respect to the charge writing under the second writing condition using a drain voltage higher than that of the first writing condition, the amount of written charges written under the second charge writing condition will be detected using a channel current in a direction that is the same as that at the time of charge writing and that is based on that threshold voltage. In this case, since the written charges written under the first writing condition enter into an area closer toward the drain than the pinch-off point, it will have little influence on the channel current, whereas the written charges written under the second charge writing condition will have greater influence over the channel current. Accordingly, it is possible to monitor the amount of written charges C2 by using the threshold voltage of control gate CG2.

Next, another method of detecting the amount of written charges will be described.

With respect to the charge injection under the first writing condition, the amount of written charges will be detected using a channel current in the same direction as in the case of writing. That is, while the control gate CG2 voltage is taken as a threshold voltage for letting the channel current reach a certain current value, it is to be determined whether the threshold voltage of control gate CG2 has reached a certain predetermined value. At this time, the drain voltage will be lowered sufficiently such that a pinch-off point will be positioned closer toward the drain than the center of distribution of the written charges written under the first writing condition.

With respect to the charge written under the second writing condition where a drain voltage is rendered higher than that of the first writing condition or where a WELL voltage is changed in a direction in which the depletion layer around the source/drain expands, it is to be determined whether the threshold voltage of control gate CG2 has reached a certain predetermined value using a channel current in a direction that is the same as in the cases of the first and the second charge writings while a pinch-off point is being shifted toward the source. The pinch-off point can be shifted toward the source by changing the drain voltage or the WELL voltage in the direction in which the depletion layer around the source/drain expands. In the case when the pinch-off point is closer toward the source than the center of the charge distribution under the first writing condition, when it is closer toward the drain than the center of the charge distribution under the second writing condition, the channel current will be greatly influenced by the charges written under the second writing condition, and therefore, it is possible to monitor the amount of written charges written under the second writing condition using the threshold voltage of control gate CG2.

As described above, it is possible to form a trapezoid-shaped accumulated charge distribution even in the case when the method of driving a semiconductor non-volatile memory, according to the present invention, is applied to the TWINMONOS type memory, whereby the charge retention characteristics can be improved.

The present invention is also applicable to a MONOS type memory which lacks one of the control gates (i.e. a trap type non-volatile memory cell where a second gate electrode is arranged next to a first gate electrode through an insulating film).

1-11. (canceled)

12. A method of driving a semiconductor device, the semiconductor device including a trap type non-volatile memory cell which includes a laminated insulating film, containing a charge accumulation layer, being formed on a semiconductor substrate where source, drain and well regions are formed, and a first gate electrode formed on the laminated insulating film, characterized by comprising:
carrying out charge injections on a single memory node multiple times under two or more different writing conditions, the writing condition being a combination of a well voltage applied to the well, a drain voltage applied to the drain, and a gate voltage applied to the first gate.

13. The method of driving a semiconductor device according to claim 12, characterized in that
the trap type non-volatile memory cell further includes a second gate electrode formed on the semiconductor substrate through a gate insulating film that is adjacent to the first gate electrode through an insulating film that is being sandwiched in between a pair of the first gate electrodes through insulating films.

14. The method of driving a semiconductor device according to claim 12, characterized in that
a drain voltage applied in a latter charge injection is higher than a drain voltage applied in a former preceding charge injection.

15. The method of driving a semiconductor device according to claim 12, characterized in that
a well voltage applied in a latter charge injection is higher than a well voltage applied in a former preceding charge injection with respect to a polarity in which a depletion layer that is around a source/drain expands.

16. The method of driving a semiconductor device according to claim 14, characterized in that
a drain voltage applied in a latter charge injection is higher than a drain voltage applied in a former preceding charge injection by 1 V or more.

17. The method of driving a semiconductor device according to claim 15, characterized in that
a voltage difference between a well voltage applied in a latter charge injection and a well voltage applied in a former preceding charge injection is 1 V or greater.

18. The method of driving a semiconductor device according to claim 12, characterized by further comprising:
determining for each charge injection whether a predetermined amount of charges, with respect to the writing condition, has been written to memory, by using a threshold detection condition corresponding to each writing condition.

19. The method of driving a semiconductor device according to claim 18, characterized by further comprising:
injecting charges under a first writing condition, then detecting the amount of written charges written by the charge injection under the first writing condition using a channel current in a direction opposite to that at the time of the charge injection, and alternately repeating the charge injection under the first writing condition and detecting of the amount of written charges until the amount of written charges reaches a first predetermined write amount; and
injecting charges under a second writing condition where a drain voltage is rendered higher than the drain voltage of the first writing condition or where a well voltage is changed in a direction where a depletion layer around the source/drain expands, the charge injection being carried out in a direction that is the same as the direction in the case of the charge injection under the first writing condition, then detecting the amount of written charges written in the charge injection under the second writing condition using a channel current in a direction that is the same as the direction at the time of the charge injection, and alternately repeating the charge injection under the second writing condition and detecting of the amount of written charges until the amount of written charges reaches a second predetermined write amount.

20. The method of driving a semiconductor device according to claim 18, characterized by further comprising:
injecting charges under a first writing condition, then detecting the amount of written charges written by the charge injection under the first writing condition using a channel current in a direction the same as the direction at the time of the charge injection, and alternately repeating the charge writing under the first writing condition and detection of the amount of written charges until the amount of written charges reaches a first predetermined write amount; and
injecting charges under a second writing condition where a drain voltage is rendered higher than the drain voltage of the first writing condition or where a well voltage is changed in a direction where a depletion layer around the source/drain expands, the charge injection being carried out in a direction that is the same as the direction in the case of the charge injection under the first writing condition, then detecting the amount of written charges written by the charge injection under the second writing condition using a channel current in a direction that is the same as the direction at the time of the charge injection while a pinch-off point is shifted closer toward the source than in a written charge detection condition with respect to the charge injection under the first writing condition, and alternately repeating the charge injection under the second writing condition and detecting of the amount of written charges until the amount of written charges reaches a second predetermined write amount.

21. A method of driving a semiconductor device, the semiconductor device including a trap type memory cell which locally accumulates signal charges in a charge trap layer, characterized by comprising:
injecting charges in such a way as to form a trapezoid-shaped accumulated charge distribution.

22. A semiconductor device including a trap type memory cell which locally accumulates signal charges in a charge trap layer, characterized by comprising:
writing the signal charges in the charge trap layer such that an electron density distribution from an edge portion of a drain will form a trapezoid shape toward a source under a state where the signal charges are written in the charge trap layer.
